(19) United States
(12) Patent Application Publication
(10) Pub. No.: US 2019/0215061 A1
(43) Pub. Date: Jul. 11, 2019

(54) DETECTION SYSTEM FOR OPTICAL TRANSCEIVER MODULE

(71) Applicant: O-NET COMMUNICATIONS (SHENZHEN) LIMITED, Shenzhen (CN)

(72) Inventors: Jiaxi KAN, Shenzhen (CN); Yanjing HU, Shenzhen (CN); Guochu ZHOU, Shenzhen (CN); Haibin LIAN, Shenzhen (CN)

(21) Appl. No.: 16/289,692

(22) Filed: Mar. 1, 2019

Related U.S. Application Data
(63) Continuation of application No. PCT/CN2018/103646, filed on Aug. 31, 2018.

(30) Foreign Application Priority Data
Jan. 5, 2018 (CN) 201810011562.4

(51) Int. Cl. H04B 10/07; H04B 10/40; G01R 27/26; G01R 31/04

(52) U.S. Cl. CPC H04B 10/07; G01R 31/046; G01R 27/2605; H04B 10/40

(57) ABSTRACT

The present disclosure provides a detection system for an optical transceiver module. The detection system comprises a detection interface connected with the PCB interface, an option switch connected with each detection conductive contact of the detection interface, and a capacitance detection assembly connected with the option switch. Each detection conductive contact of the detection interface is correspondingly inserted into and connected with the conductive contact of the I/O interface of the PCB interface. The capacitance detection assembly is electrically connected with each detection conductive contact of the detection interface by the option switch to obtain capacitance value of corresponding conductive contact of the detection interface.

### CROSS-REFERENCE TO RELATED APPLICATIONS

This is a continuation-application of International Application No. PCT/CN2018/103646, with an international filing date of Aug. 31, 2018, which claims foreign priority to Chinese Patent Application No. 201810011562.4, filed on Jan. 5, 2018 in the State Intellectual Property Office of China, the contents of all of which are hereby incorporated by reference in their entirety.

### TECHNICAL FIELD

The present disclosure relates to the technical field of optical transceiver module, and in particular to a detection system for an optical transceiver module.

### BACKGROUND

An active optical fiber cable (AOC) as alternative scheme of the new-generation data transmission is known from the world since 2007. Portable optical-fiber cables simultaneously transmitted four-paths optical fiber signals and retains electrical interface as a conventional cable at the same time, which makes the AOC technology maintain signal integrity within a transmission distance of 1 to 100 meters. As the optical fiber has light weight, good curved characteristic, has a bit error rate (BER) greater than copper cable, the optical fiber is manufactured in large volumes.

During manufacturing of a 40 G/100 G optical transceiver module, a certain proportional of failure of RF I/O path is generated, which shows capacitance fracture, virtual welding of gold-wire, gold-line fracture and so on, further causing failure of products.

Entire periodic line (namely I/O path) is formed by follow way: chip of the products have differential pin (I/O pin), the I/O pin is connected with a first end of a capacitor by the gold-line, and a second end of the capacitor is connected with a gold-finger of the products. The gold-finger is an electric interface.

### SUMMARY

The technical problem solved by the present disclosure is to provide a detection system for an optical transceiver module capable of determining connection of periodic line is normal by detecting capacitance value of the periodic line, further avoiding failure product inflow customers.

In order to solve the technical problem mentioned above, the present disclosure provides a detection system for an optical transceiver module, where the optical transceiver module comprises a high frequency chip and a printed circuit board (PCB) interface, conductive contacts of input/output (I/O) interface of the PCB interface is one to one correspondingly connected with signal paths of the I/O interface of the high frequency chip, a capacitor is connected in series between each detection conductive contact and each corresponding signal circuit as the AC coupling. The detection system comprises a detection interface connected with the PCB interface, an option switch connected with each detection conductive contact of the detection interface, and a capacitance detection assembly connected with the option switch. Each detection conductive contact of the detection interface is correspondingly inserted into and connected with the conductive contact of the I/O interface of the PCB interface. The capacitance detection assembly is electrically connected with each detection conductive contact of the detection interface by the option switch to obtain capacitance value of corresponding conductive contact of the detection interface.

Furthermore, the detection system comprises a data processing assembly connected with the capacitance detection assembly, where the data processing assembly sets a capacitance threshold. Capacitance value of all signal paths of the I/O interface of the high frequency chip are compared with the capacitance threshold, if the capacitance value is in the capacitance threshold, result is qualified, if the capacitance value is not in the capacitance threshold, result is failured.

Furthermore, the data processing assembly comprises a read module, and we can obtain the module information of the high frequency chip connected with the detection interface.

Furthermore, the detection system comprises a data storing assembly, where the data storing assembly stores the capacitance value of all signal paths of the I/O interface of the high frequency chip.

Furthermore, the option switch comprises an option element and a control element. The capacitance detection assembly is electrically connected with each detection conductive contact of the detection interface by the control element of the option switch.

Furthermore, the option element is a switch chip having one of sixteen different choices.

Furthermore, the detection system comprises a trigger module, where the trigger module is respectively connected with the capacitance detection assembly and the control element. After the capacitance detection assembly obtains the capacitance value of the corresponding conductive contact of the detection interface, the control element is triggered by the trigger module. The triggered control element controls the option element to switch channel.

Furthermore, position of the conductive contacts of the I/O interface of the PCB interface one to one corresponds to position of the detection conductive contact of the detection interface.

Furthermore, the detection system comprises a supply circuit, where the supply circuit is electrically connected with the high frequency chip to provide power source for the high frequency chip.

Furthermore, the detection interface comprises a supply conductive contact connected with the supply circuit. Position of supply conductive contact matches with position of a power supply of the PCB interface.

The benefit effects of the present disclosure are: compared with the prior art, the present disclosure uses the detection interface to connect with the I/O interface of the high frequency chip, and obtains the capacitance value of the I/O periodic line by the option switch and the capacitance detection assembly, further determining connection situation of the high frequency I/O path, such as capacitance fracture, virtual welding of gold-wire, gold-line fracture. The present disclosure uses the periodic line to detect, which improves yield rate of the products, avoids failure product inflowing client, and uses quickly detection structure of the detection interface, further improving detection efficiency.

### BRIEF DESCRIPTION OF THE DRAWINGS

The present disclosure will be further described with reference to the accompanying drawings and embodiments:

FIG. 1 is a structural diagram of a detection system of the present disclosure.

FIG. 2 is a structural diagram of a detection system based on interfaces of the present disclosure.

FIG. 3 is a structural diagram of a high frequency chip connected with a printed circuit board interface of the present disclosure.

FIG. 4 is a circuit diagram of an input end of FIG. 3 of the present disclosure.

FIG. 5 is a circuit diagram of an output end of FIG. 3 of the present disclosure.

FIG. 6 is a structural diagram of a data processing assembly of the present disclosure.

FIG. 7 is a structural diagram of a processing interface of the data processing assembly of the present disclosure.

FIG. 8 is a structural diagram of an option switch of the present disclosure.

FIG. 9 is a structural diagram of a trigger module of the present disclosure.

FIG. 10 is a structural diagram of a supply circuit of a first embodiment of the present disclosure.

FIG. 11 is a structural diagram of a supply circuit of a second embodiment of the present disclosure.

### DETAILED DESCRIPTION

The following will clearly and completely describe the technical solutions in the embodiments of the present disclosure with reference to the accompanying drawings in the embodiments of the present disclosure.

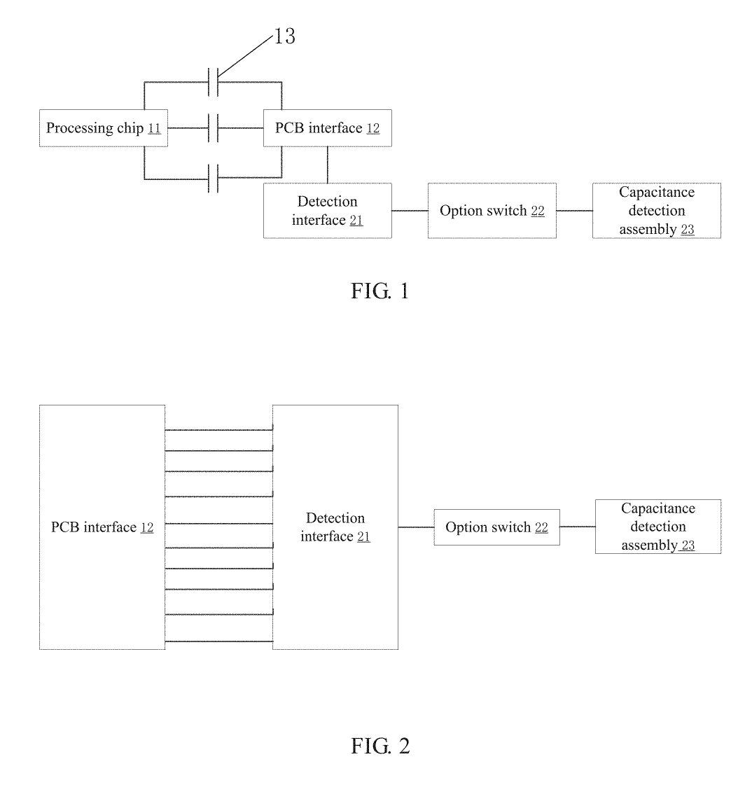

As shown in FIG. 1 and FIG. 2, the present disclosure provides an embodiment of a detection system for an optical transceiver module.

The optical transceiver module comprises a high frequency chip 11 and a printed circuit board (PCB) interface 12, where conductive contacts of input/output (I/O) interface of the PCB interface 12 is one to one correspondingly connected with signal paths of I/O interface of the high frequency chip 11, a capacitor 13 is connected in series between each detection conductive contact and each corresponding signal path. The detection system comprises a detection interface 21 connected with the PCB interface 12. The detection system comprises a detection interface 21 connected with the PCB interface 12, an option switch 22 connected with each detection conductive contact of the detection interface 21. The capacitance detection assembly 23 is electrically connected with each detection conductive contact of the detection interface 21 by the option switch 22 to obtain capacitance value of corresponding conductive contact of the detection interface 21.

The present disclosure is used for detecting the optical transceiver module or a circuit board disposed in the optical transceiver module. For example, the high frequency chip and an external circuit are disposed on the circuit board, and the PCB interface 12 is disposed on an edge of the circuit board. The PCT interface 12 is connected with a pin of the high frequency chip 11 by the external circuit. The conductive contacts of the I/O interface of the PCB interface 12 is one to one correspondingly connected with signal paths of the I/O interface of the high frequency chip 11. The capacitor 13 is connected in series between each detection conductive contact and each corresponding signal path. When the high frequency chip 11 is normally working or the high frequency chip 11 is connected with the external circuit, capacitance of the conductive contacts of the I/O interface of the PCB interface 12 is detected, the detected capacitance value of the conductive contacts of the I/O interface of the PCB interface 12 should be same as or close to capacitance value of the capacitor 12 based on the PCB interface 12, internal periodic line and capacitor 3 at normal operation.

Otherwise, if the problem, such as capacitance fracture, virtual welding of gold-wire, and gold-line fracture, is appeared, the detected capacitance value of the conductive contacts of the I/O interface of the PCB interface 12 should unmoral.

Furthermore, position of the conductive contacts of the I/O interface of the PCB interface 12 one to one corresponds to position of the detection conductive contact of the detection interface 21. The present disclosure uses an interface of the optical transceiver module as the detection interface 21, the option switch 22 only is connected with each detection conductive contact of the detection interface 21. It should be understood that, the present disclosure uses a special interface as the detection interface 21, namely the detection interface 21 only retain the detection conductive contact corresponding to the conductive contacts of the I/O interface of the PCB interface 12.

To be specific, the PCB interface 12 inserts into the detection interface 21 to electrically connect, and the option switch 22 is turned on. Each detection conductive contact of the detection interface 21 is electrically connected with the capacitance detection assembly 23 by the option switch 22, namely the capacitance detection assembly 23 is electrically connected with each conductive contact of the I/O interface of the PCB interface 12 to detect the capacitance value of the capacitor 12 between the signal path of the I/O interface of the high frequency chip and the I/O interface of the PCB interface.

Generally speaking, the detection interface 21 and the option switch 22 are disposed on a same circuit board, are connected with the PCB interface 12 by the detection interface 21, and are connected with the capacitance detection assembly 23 by wire leads. It should be understood that, a specific capacitance detection assembly 23, the detection interface 21 and the option switch 22 are disposed on the same circuit board, and transmits detection data by the wire leads.

The capacitance detection assembly 23 comprises a capacitor meter, a multimeter, or other device detecting the capacitor 13. For example, type of desktop multimeter is GDM-8246.

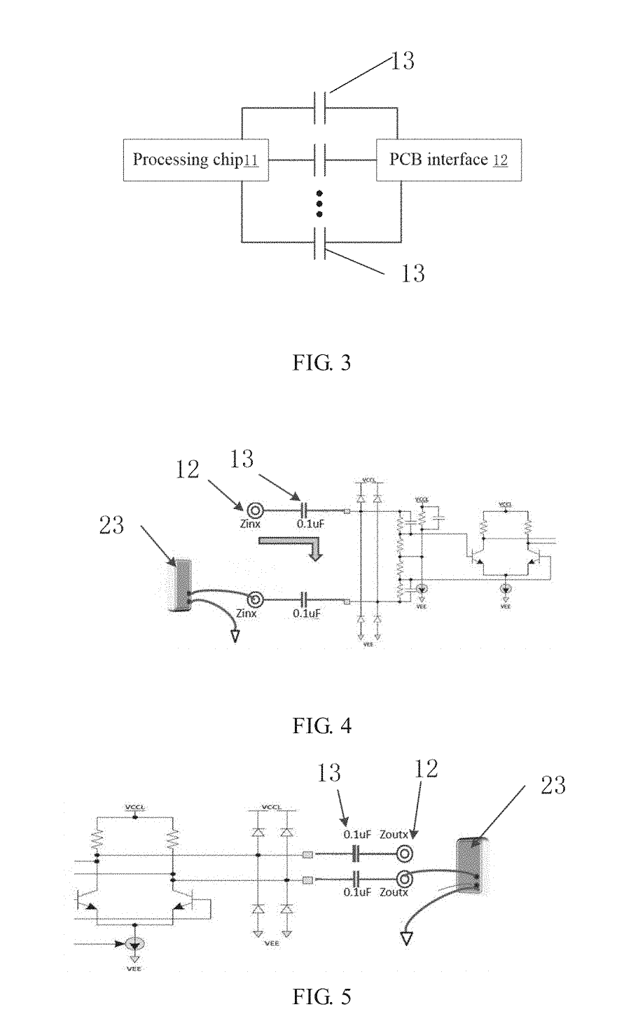

As shown in FIG. 3 to FIG. 5, the present disclosure provides an embodiment that the high frequency chip is connected with the PCB interface.

Input and output ends of the optical transceiver module have four-paths differential pairs, respectively, corresponding to sixteen paths signal periodic line. Each periodic line has one capacitor with 0.1 uf. As shown in FIG. 4 and FIG. 5, the input end of the optical transceiver module has four paths differential pairs, the output end of the optical transceiver module has four paths differential pairs, and one-path differential pair corresponds to two paths signals, thus, the input/output ends of the optical transceiver module have sixteen paths signals.

To be specific, one capacitor with 0.1 uf is between the I/O pin of the high frequency chip and gold-finger of the print circuit board in each channel. The capacitance value of the capacitor 13 in each path is obtained by the capacitance detection assembly 23 to determine the problem, such as capacitance fracture, virtual welding of gold-wire, and gold-line fracture.

Differential circuit has characteristics with restraining common-mode signal and amplifying different-mode signal. Two signals input the input end of the differential circuit, difference between the two signals is an effective input signal of the differential circuit. The output of the differential circuit is to amplify the effective input signal. If interrupt signal exists, same interference can be generated for the two signals, effective input signal of the interrupt signal is zero to avoid common-mode interference.

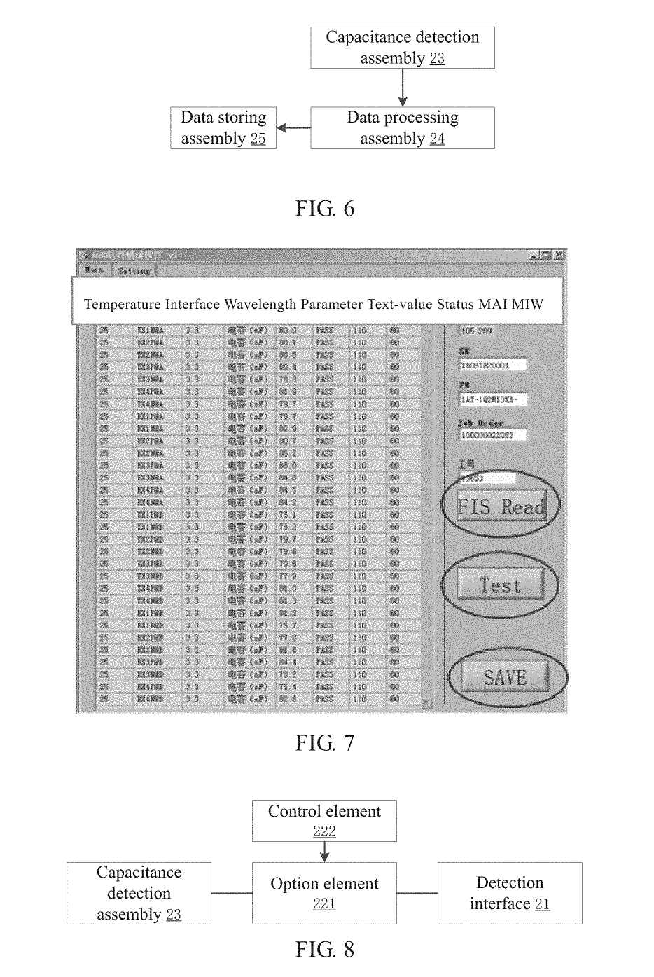

As shown in FIG. 6 and FIG. 7, the present disclosure provides the data processing assembly of the embodiment.

The detection system comprises the data processing assembly 24 connected with the capacitance detection assembly 23. The data processing assembly 24 sets a capacitance threshold, capacitance value of all signal paths of the I/O interface of the high frequency chip are compared with the capacitance threshold, if the capacitance value is in the capacitance threshold, result is qualified, if the capacitance value is not in the capacitance threshold, result is unqualified.

Generally speaking, the data processing assembly 24 can be a computer device or a processor, which is use to determine if detected capacitance value is in the capacitance threshold, further determining welding situation of the periodic line or situation of the capacitor 13.

In the embodiment as shown in FIG. 7, the data processing assembly 24 comprises a read module. The read module obtains module information of the high frequency chip 11 connected with the detection interface 21. To be specific, each optical transceiver module or each high frequency chip both sets a reference code. The reference code is obtained before detecting, which is easy for data cleansing, data feedback, data backtracking.

The above testing process comprise: 1. Obtaining the reference code (namely clicking FIS READ) and displaying; 2. Testing (namely clicking Text) and display test result, in particular to testing value of the capacitor 13; 3. Storing data and result.

The detection system further comprises a data storing assembly 25, where the data storing assembly stores the capacitance value of all signal paths of the I/O interface of the high frequency chip. The data storing assembly 25 can be hard disk or storing device in the computer.

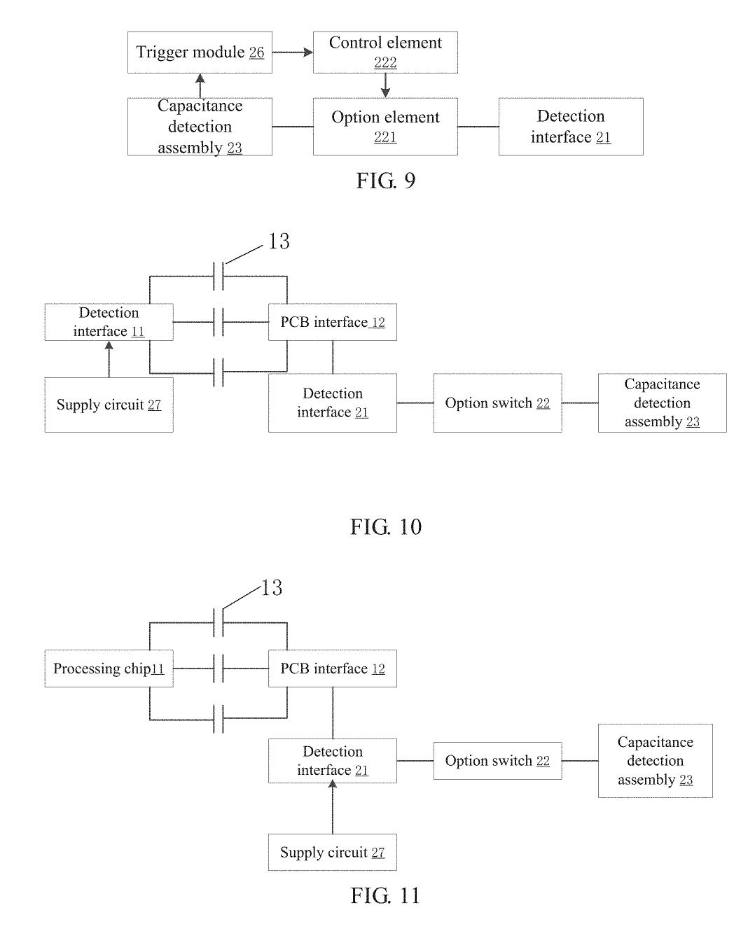

As shown in FIG. 8 and FIG. 9, the present disclosure provides the option switch of the embodiment.

The option switch 22 comprises an option element 221 and a control element 222. The capacitance detection assembly 23 is electrically connected with each detection conductive contact of the detection interface 21 by the control element 222 of the option switch 22.

Furthermore, the option element is a switch chip having one of sixteen different choices. For example, the type of the switch chip is MUX506.

In the embodiment as shown in FIG. 9, the detection system further comprises a trigger module 26. The trigger module 26 is respectively connected with the capacitance detection assembly 23 and the control element 222. After the capacitance detection assembly obtains the capacitance value of the corresponding conductive contact of the detection interface, the control element is triggered by the trigger module. The triggered control element 222 controls the option element 221 to switch channel.

It should be understood that timing switch way is used. The option element 221 is controlled to switch by timing operation.

As shown in FIG. 10 and FIG. 11, the present disclosure provides a supply circuit of the embodiment.

The detection system further comprises a supply circuit 27. The supply circuit 27 is electrically connected with the high frequency chip 11 to provide power source for the high frequency chip. For example, a current power source M8811 is used to provide the power source for the high frequency chip 11.

Furthermore, the detection interface 21 comprises a supply conductive contact connected with the supply circuit 27. Position of supply conductive contact matches with position of a power supply of the PCB interface 12.

The foregoing descriptions are merely implementation manners of the present disclosure, and therefore do not limit the scope of patents of the present disclosure. Any equivalent structure or equivalent process transformation using the description of the present disclosure and the accompanying drawings may be directly or indirectly applied to other related technologies. The same applies in the field of patent protection of this disclosure.

What is claimed is:

1. A detection system for an optical transceiver module, the optical transceiver module comprising a high frequency chip and a printed circuit board (PCB) interface, conductive contacts of input/output (I/O) interface of the PCB interface are one to one correspondingly connected with signal paths of the I/O interface of the high frequency chip, a capacitor is connected in series between each detection conductive contact and each corresponding signal circuit, the detection system comprising:
a detection interface connected with the PCB interface;
an option switch connected with each detection conductive contact of the detection interface; and
a capacitance detection assembly connected with the option switch;
wherein each detection conductive contact of the detection interface is correspondingly inserted into and connected with the conductive contact of the I/O interface of the PCB interface;
wherein the capacitance detection assembly is electrically connected with each detection conductive contact of the detection interface via the option switch to obtain capacitance value of corresponding conductive contact of the detection interface.

2. The detection system for the optical transceiver module according to claim 1, further comprising a data processing assembly connected with the capacitance detection assembly, the data processing assembly sets a capacitance threshold, capacitance value of all signal paths of the I/O interface of the high frequency chip are compared with the capacitance threshold, if the capacitance value is in the capacitance threshold, result is qualified, if the capacitance value is not in the capacitance threshold, result is unqualified.

3. The detection system for the optical transceiver module according to claim 2, wherein the data processing assembly comprises a read module; the read module obtains module information of the high frequency chip connected with the detection interface.

4. The detection system for the optical transceiver module according to claim 2, further comprising a data storing assembly; the data storing assembly stores the capacitance value of all signal paths of the I/O interface of the high frequency chip.

5. The detection system for the optical transceiver module according to claim 1, wherein the option switch comprises an option element and a control element; the capacitance detection assembly is electrically connected with each detection conductive contact of the detection interface by the control element of the option switch.

6. The detection system for the optical transceiver module according to claim 4, wherein the option element is a switch chip having one of sixteen different choices.

7. The detection system for the optical transceiver module according to claim 4, further comprising a trigger module; the trigger module is respectively connected with the capacitance detection assembly and the control element; after the capacitance detection assembly obtains the capacitance value of the corresponding conductive contact of the detection interface, the control element is triggered by the trigger module; the triggered control element controls the option element to switch channel.

8. The detection system for the optical transceiver module according to claim 1, wherein position of the conductive contacts of the I/O interface of the PCB interface one to one corresponds to position of the detection conductive contact of the detection interface.

9. The detection system for the optical transceiver module according to claim 1, further a supply circuit; the supply circuit is electrically connected with the high frequency chip to provide power source for the high frequency chip.

10. The detection system for the optical transceiver module according to claim 1, wherein the detection interface comprises a supply conductive contact connected with the supply circuit; position of supply conductive contact matches with position of a power supply of the PCB interface.
